(19) United States
(12) Patent Application Publication
(10) Pub. No.: US 2017/0084703 A1
(43) Pub. Date: Mar. 23, 2017

(54) Multi-Trench Semiconductor Devices

(71) Applicant: Diodes Incorporated, Plano, TX (US)

(72) Inventors: Yun-Pu Ku, New Taipei City (TW); Chiao-Shun Chuang, Zhubei City (TW); Cheng-Chin Huang, Plano, TX (US)

(21) Appl. No.: 14/856,709

(22) Filed: Sep. 17, 2015

(51) Int. Cl. H01L 29/40; H01L 29/78; H01L 21/28; H01L 29/66; H01L 29/06; H01L 29/423

(52) U.S. Cl. CPC H01L 29/402; H01L 29/0684; H01L 29/4236; H01L 21/28008; H01L 29/66666; H01L 29/7827

(57) ABSTRACT

A MOSFET device or a rectifier device with improved RDSON and BV performance has a repetitive pattern of field plate trenches disposed in a semiconductor chip. The semiconductor chip comprises a doped epi-layer, in which the dopant concentration progressively decreases from the top of the chip surface towards the bottom of the chip. The doped epi-layer may comprises strata of epi-layers of different dopant concentrations and the field plate trenches each terminate at a predetermined point in the strata.

This application claim priority of a PCT application number PCT/US15/42776, filed on Jul. 30, 2015. The content of which is incorporated herein in its entirety.

### BACKGROUND

The performance of power semiconductor devices in general and of trench (vertical) devices in particular is defied by several parameters. Among them the on-resistance R_{DSON} and the breakdown voltage BV seem to counteract each other in the sense that the improvement on one often comes at the expense of the other. For example, when the dopant concentration among the current path increases, which results in on-resistance R_{DSON} improvement, the breakdown voltage BV drops, which is detrimental to the device performance. Several approaches have been proposed to push the boundary of the counterbalance between the on-resistance and the breakdown voltage.

One approach is proposed by Texas Instruments (TI) in US 2010/0264486 A1 and is later demonstrated by Toshiba (Kobayashi et al. Proceedings of the 27th International Symposium on Power Semiconductor Devices & ICs, 2015). It proposes to vary the thickness of the oxide of the field plate in the trenches. Specifically, the oxide of the field plate structure is made progressively thicker in distinct steps from the top end of the trench toward the bottom of the trench. There is a five-year span between the TI publication and the Toshiba demonstration.

Another approach proposed by Maxpower (U.S. Pat. No. 8,354,711 B2) is to divide the field plate structure into multiple mutually isolated sections, where each section has an independent field plate that it can be biased independent of other sections in each trench.

### SUMMARY

Inventors recognize that although the theories behind the proposed approaches are plausible, there are serious manufacturing challenges that will make such devices difficult to mass produce. In the TI process, for example, there are at least two transition points in the field plate trench that divide the field plate structure into at multiple sections, and the sections each have narrowly defined length and oxide thicknesses. The control of the multiple etching processes and the control of the different oxide thicknesses are critical and challenging.

The Maxpower proposal calls for multiple mutually isolated field plates in the trenches and the field plates are separated by thin layers of silicon dioxide film. To be effective, the multiple field plates need to be individually biased electrically. The biasing necessarily adds complexity to the design and device operation. In addition, the device depends on the precise placement of the oxide films in the trench with respect to the doped layers and this adds difficulties in device fabrication.

The Inventors also recognize that in modern semiconductor process technology, certain processes are more readily controllable. Among them are epitaxial layer growth, trench etching, and oxide film formation on crystalline silicon surfaces. By taking advantage of the more easily controlled processes, Inventors invented a novel methodology that can be adapted easily in fabricating devices such as power MOSFETs and power rectifiers.

The novel processes are based on placing field plate trenches of pre-defined depths in strata of semiconductor epi-layers of specific resistivities. In its simplest implementation, field plate trenches of two alternate different depths are disposed in a repetitive pattern. The depth of the shallower trench is about equal to the thickness of a first epi-layer, and the depth of the deeper trench is less than the accumulated thickness of the first epi-layer and a second epi-layer that lies immediately below the first epi-layer. In other words, the shallower trench traverses the first epi-layer and the deeper trench penetrates fully the first epi-layer and partially the second epi-layers. The first and the second epi-layers have different dopant concentrations—the first epi-layer being more heavily doped than the second epi-layer. The dominating dopants in both epi-layers are of the same polarity.

The field plate trenches are configured to be close to the p-n junction that is designed to sustain high reverse bias and the depletion region in the epi-layers associated with the p-n junction. One such configuration is a trench with a core of doped polysilicon that is electrically isolated from the trench walls by a layer of silicon dioxide. With the polysilicon core properly bias with respect to the p-n junction, the peak electric field at the spots that tend to reach breakdown early will be reduced so the p-n junction can sustain a higher reverse bias voltage across it.

The inventive concept behind this two-trench configuration can be readily expanded to three or more trenches and three or more epi-layer strata. Exemplary implementations in a following section will be used to explain this inventive concept more fully.

Suffice to say that a person skilled in the art of semiconductor processing can read this disclosure and appreciate the robustness of the processes with which the invention may be implemented and the predictable good device performance as a result. This is because the implementation of this invention does not depend on the difficult to control steps as prescribed in the known art and the robustness of the implementation of the embodiments described below is apparent.

### DEFINITION

The terms used in this disclosure generally have their ordinary meanings in the art within the context of the invention. Certain terms are discussed below to provide additional guidance to the practitioners regarding the description of the invention. It will be appreciated that same thing can be said in more than one way. Consequently, alternative language and synonyms may be used.

A semiconductor chip is a slab of semiconducting material such as silicon, germanium, silicon carbide, diamond, gallium arsenide, and gallium nitride. A semiconductor chip usually has two parallel surface planes, which are major crystallographic planes. Integrated circuits are built in and on the top surface of semiconductor chips; recently, some integrated circuit elements have been build perpendicular to the top surface into the bulk of the semiconductor chips. In this disclosure, the term top surface of the chip or chip surface is used to mean the top parallel surface of the semiconductor chip where the semiconductor material comes in contact with other material such as dielectric or conductive materials.

A trench is a structural element in certain integrated circuit chips. Trenches are usually formed from a patterned image in a photoresist film on the semiconductor chip surface, followed by removing material from the chip where photoresist is absent. The removal of material is usually done with a reactive ion etching process. Trenches when viewed from the chip surface usually have long-striped repetitive pattern. The walls of a trench are the vertical surfaces of the semiconductor material extending from the surface of the chip to the bottom of the trench. In this disclosure, the width of a trench is the distance between two opposing trench walls and the length of the trench is the long dimension that is orthogonal to the width and the depth of the trench. The depth of a trench is measured in a direction that is perpendicular to the top surface of the chip and is the measurement from the top surface of the chip to the endpoint of the etching step, i.e. the bottom of the trench.

A MOSFET is a four-terminal electronic circuit element. Electrical current can flow in a channel between the source terminal and the drain terminal, and the magnitude of the current may be controlled by the voltages at the gate terminal and at the body region. In a MOSFET, current can flow in both direction of the channel. In many trench MOSFETs, the gate is built in the trench, and the body region is shorted internally to the source region.

A Rectifier is a two-terminal electrical circuit element. Electrical current may or may not flow between the anode and the cathode depending on the polarity of the voltage across the terminals. In a SBR rectifier made by Diodes Incorporation, there is also a gate structure. SBR rectifier can also be built vertically with trenches in which a gate or a field plate or both are disposed.

An epitaxial layer (epi-layer) in this disclosure refers to a layer of single crystal semiconductor formed on a substrate of, for example, another single crystal semiconductor layer by epitaxial growth. The substrate may be heavily doped to reduce device resistance. Dopant may be incorporated into an epi-layer during its formation, or afterwards through ion-implantation. Integrated circuit elements are usually built in epi-layer or layers. In this disclosure, the semiconductor chip comprises strata of epi-layers that have different dopant concentration. The difference in dopant concentration between two adjacent epi-layers may be as little as 5% when the epi-layers are initially formed. During device fabrication, high temperature processes may cause the dopant in the epi-layers to diffuse so at the completion of the fabrication process, the interface between adjacent epi-layers may lose its sharpness and becomes an interface zone or region in which the dopant concentration changes gradually. The zone may in some cases occupy up to 30% of the thickness of the epi-layers.

Source and Drain in a MOSFET refer to the source and drain terminals or the two regions in a semiconductor chip that are connected to the respective terminals. In a vertical MOSFET, the drain can either be at the top of the chip surface in a configuration known as source-down, or at the bottom of the chip in a configuration known as drain-down.

Forward Voltage (V_{F}) of a MOSFET or a rectifier is the measurement of voltage at the device when a specific amount of current flows through it. It is a figure of merit in power devices as it represents the power loss (IV_{F}) due to ohmic heating when the device is forward driven

On-resistance (R_{DSON}) of a MOSFET or a rectifier is the measurement of current of a device forward driven at a set voltage. It is a figure of merit in power devices as it represents the power loss due to ohmic heating.

Block voltage (BV) of a MOSFET or a rectifier is the measurement of the maximum voltage across a reverse biased junction of a device before it enters into “breakdown” mode. It is a figure of merit in power devices as it represents the maximum operation voltage of the device.

A Field plate in a power MOSFET or a rectifier is a conductive element disposed near a p-n junction and when properly biased can effectively alter the electrical field distribution near the p-n junction to increase its breakdown voltage. The filed plate may be a polysilicon structure at the surface of the device or inside a field plate trench. A field plate trench in a vertical MOSFET or rectifier has a conductive element such as doped polysilicon disposed inside the trench and shielded from the MOSFET channel by a layer of dielectric material. It is configured to increase the breakdown voltage between the body region and the substrate.

### BRIEF DESCRIPTION OF THE DRAWINGS

FIG. 1 depicts a cross section view of a partially completed device that embodies certain aspects of this invention.

FIG. 2 depicts a cross section view of a partially completed device that embodies certain aspects of this invention.

FIGS. 3 and 3A depict a cross section view of a partially completed device that embodies certain aspects of this invention.

FIGS. 4 and 4A depict a cross section view of a partially completed device that embodies certain aspects of this invention.

FIG. 5 depicts a cross section view of a partially completed device that embodies certain aspects of this invention.

FIG. 6 depicts a cross section view of a partially completed device that embodies certain aspects of this invention.

FIG. 7 depicts a portion of a trench mask including a repetitive pattern of two trenches.

### DETAIL DESCRIPTION OF EXAMPLES

### Example 1

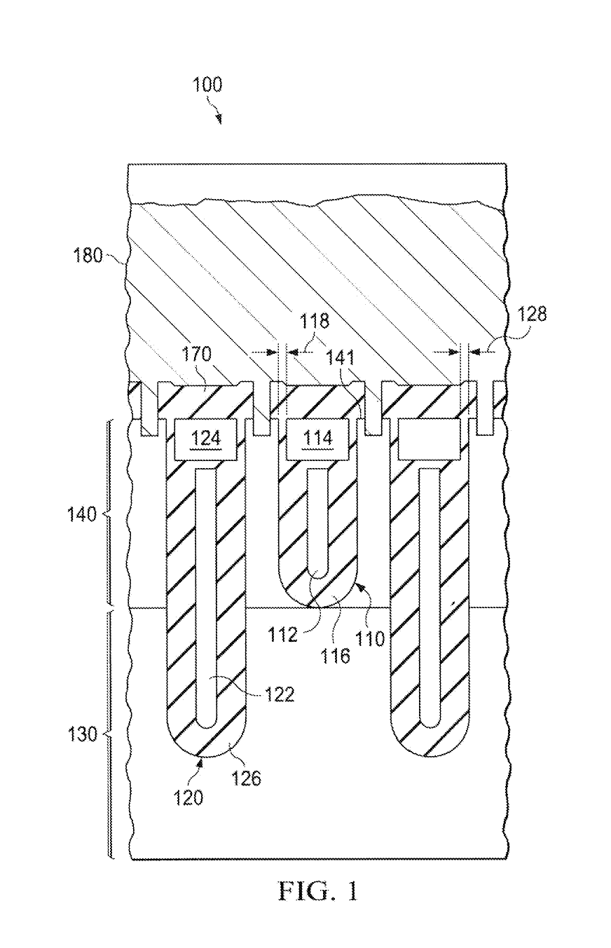

FIG. 1 depicts the schematic cross section view of a partially completed device 100 that embodies some aspects of this invention. This device may be a power MOSFET or a power rectifier and is built in a silicon chip that comprises two epi-layers 130 and 140. Both epi-layers are doped predominately with n-type dopant and epi-layer 140 is more heavily doped than the epi-layer 130. At the middle of FIG. 1 is a field plate trench 110 and two other field plate trenches 120 flanking the field trench 110. Trenches 110 and 120 are etched downwardly from the chip surface 141. The bottom of the trench 110 is at the interface region of the two epi-layers 140 and 130. Trenches 120 are etched deeper than trench 110 and their bottoms penetrate into the epi-layer 130, past the interface region of the epi-layer 130 and the epi-layer above it.

In each field plate trench depicted in FIG. 1 there are two sections of polysilicon material. In trench 110, the lower section 112 is the field plate electrode and the upper section 114 is the gate electrode. The two sections are insulated from each other by a dielectric layer, which in this example comprises silicon dioxide. Other dielectric materials such as silicon oxynitride may also be used.

The field plate electrode 112 is space from the epi-layer 140 by a dielectric layer 116 and the gate electrode 114 is space from the epic layer 140 by the gate oxide layer 118. In this example, the gate oxide layer comprises silicon dioxide. Other dielectric material such as silicon oxynitride and other metal oxide may also be used. The epi-layer 140 near the gate oxide 118 may be counter doped with a p-type dopant such as boron. This region is known in the art as the body region of the MOSFET or the rectifier. As is depicted in FIG. 1, the dielectric layer 116 is thicker than the gate oxide 118.

Flanking the field plate trench 110 are two field plate trenches 120, which are deeper than the field plate trench 110. In trenches 120, the lower section of the polysilicon material 122 is the field plate electrode and the upper section 124 is the gate electrode. The two sections are also insulated from each other by a dielectric layer, which in this example comprises silicon dioxide. Other dielectric materials such as silicon oxynitride may also be used.

The field plate electrode 122 is space from the epi-layer 140 by a dielectric layer 126 and the gate electrode 124 is space from the epic layer 140 by the gate oxide layer 128. In this example, the gate oxide layer comprises silicon dioxide. Other dielectric material such as silicon oxynitride and other metal oxide may also be used. The epi-layer 140 near the gate oxide 118 may be counter doped with a p-type dopant such as boron. This region is known in the art as the body region of the MOSFET or the rectifier. As is depicted in FIG. 1, the dielectric layer 126 is thicker than the gate oxide 128. The thickness of the dielectric layer 126 is similar to the thickness of the dielectric layer 116, and the thickness of the gate oxide layer 128 is similar to the thickness of the gate oxide layer 118.

Over the gate electrodes 114 and 124 is a layer of dielectric material 170, which in this example is silicon dioxide. Other dielectric material such as silicon nitride and silicon oxynitride and other metal oxide may also be used. The dielectric material layer 170 insulates the gate electrodes 114 and 124 from a metal layer 180, which makes contact with the epi-layer 140 and the body region near the chip surface 141.

The metal layer 180 may comprise metal such as aluminum, copper, titanium, platinum, or a combination of metals. At the interface of the metal 180 and the epi-layer 140, there may be formation of Schottky diode, tunnel diode, or ohmic contact, depending on the metal and the dopant species and concentration in the epi-layer 140 at the contact.

The device 100 is a MOSFET if the epic-layer near the gate electrodes 114 and 124 at the top of the body region is counter-doped with n-type dopant such as phosphorous and arsenic to make a source region. If the source region is absent, device 100 may be a rectifier.

### Example 2

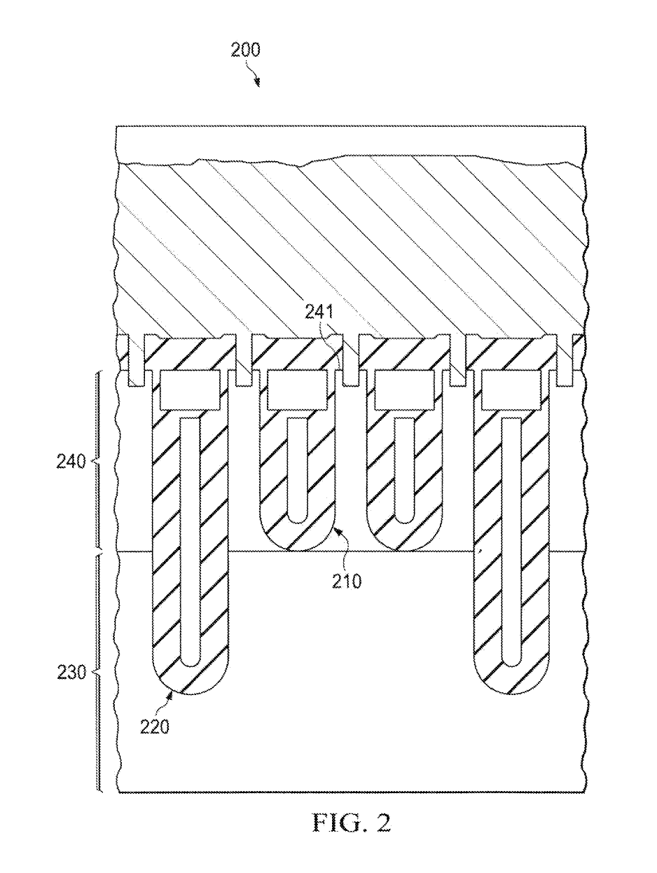

FIG. 2 depicts the schematic cross section of another device 200, which also embodies some aspects of this invention. Device 200 may be a MOSFET or a rectifier.

Device 200 comprises a repetitive pattern of field plate trenches 210 and 220, both are etched from the chip surface 241 into a semiconductor chip. The etching of the field plate trenches 210 stops when the bottoms reach the interface region of the epi-layers 230 and 240. The field plate trenches 220 are etched deeper than the trenches 210. In this embodiment, the etching continues through the interface region of the epi-layer 230 and the epi-layer 240 above the epi-layer 230, and stops after the bottoms penetrate into the epi-layer 230. In this aspect, the device 200 is similar to the device 100 described in the previous paragraphs.

What differentiates the device 200 from the device 100 is that in device 200, the two shallow field plate trenches 210 are disposed next to each other while in the device 100 each shallow field plate is flanked on both sides by a deeper field plate trench 120.

### Example 3

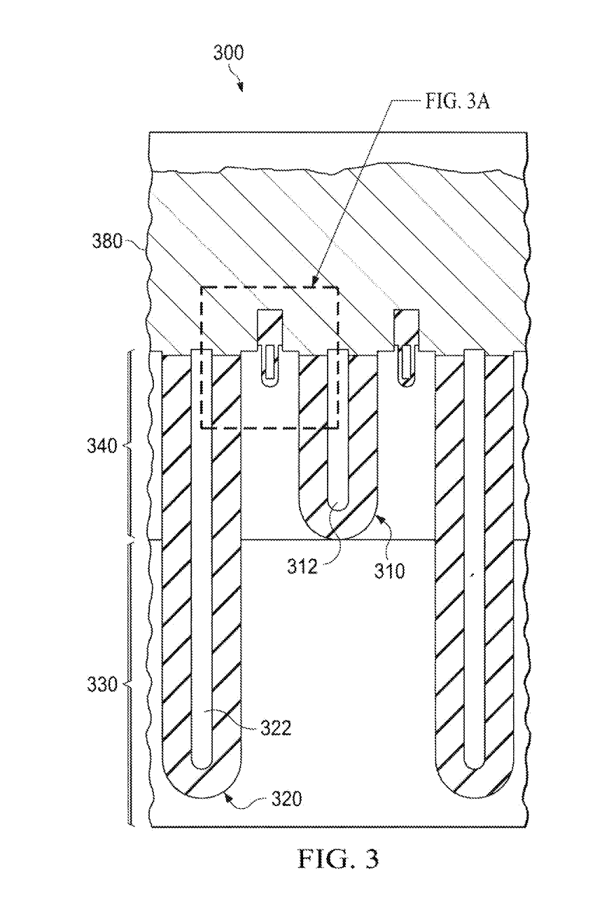

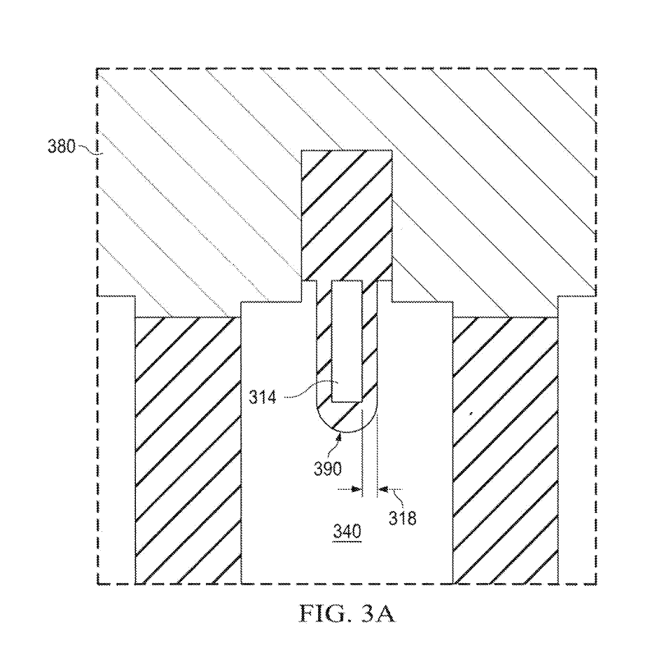

FIGS. 3 and 3A depict the schematic cross section of another device 300, which also embodies some aspects of this invention. Device 300 may be a MOSFET or a rectifier.

In the device 300, the gate electrodes and the field plate electrodes are not disposed in common trenches as the devices 100 and 200 are, but are disposed in separated trenches.

The repetitive pattern of field plate trenches of device 300 is similar to the pattern depicted in FIG. 1. The field plate trench 310 corresponds to the field plate trench 110 of FIG. 1 and field plate trenches 320 correspond to the field plate trenches 120. The gate electrodes 314, however, are in gate trenches 390, which are disposed between adjacent field plate trenches 310 and 320. The gate electrode 314 is spaced from the epi-layer 340 by the gate dielectric 318. The field plate electrodes 322 come in contact with the metal element 380, which in this example also contacts the epi-layer 340 near the top surface of the chip. If the field plate electrodes 322 and 312 need to be biased at an electric potential different from the source potential, then the electrodes will be electrically insulated from each other.

Similar to devices 100 and 200, the field plate trench 310 bottoms near the border of the two epi-layers 340 and 330, and the deeper field plate trench passes the transition region of the two adjacent epi-layers.

### Example 4

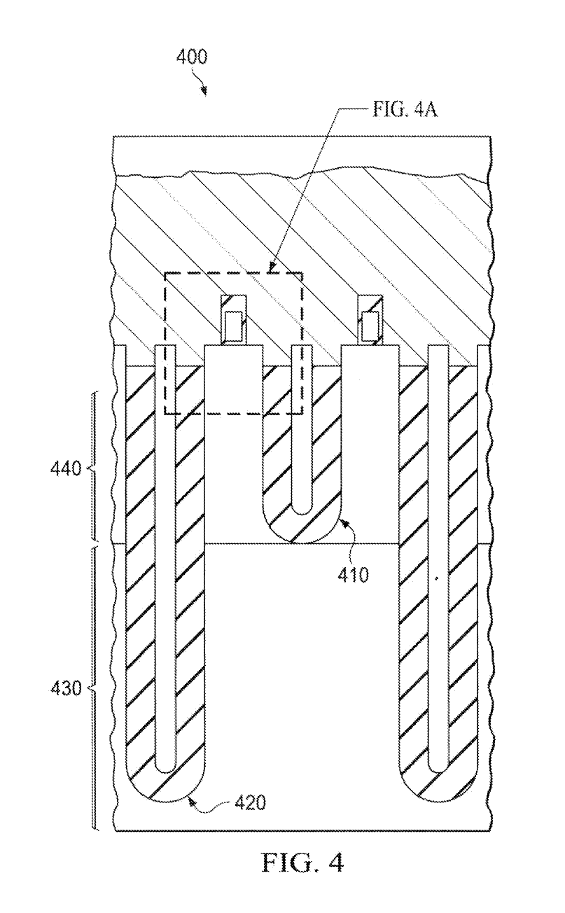

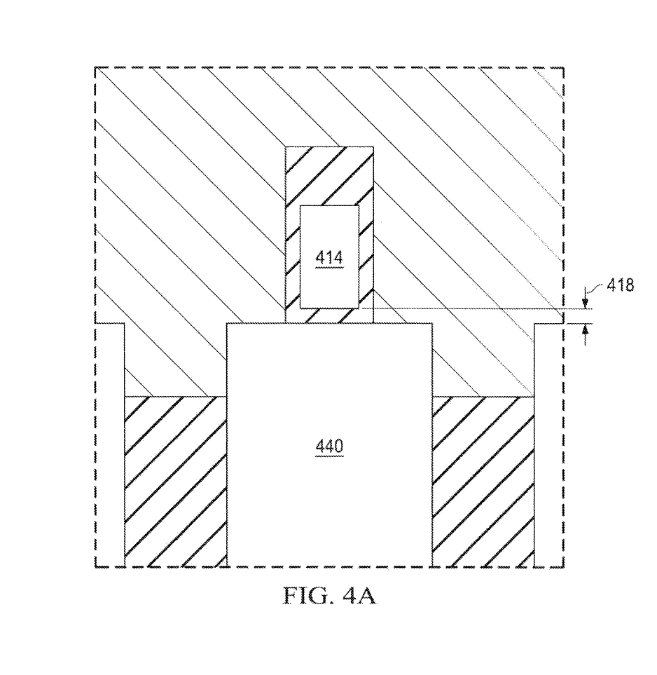

FIGS. 4 and 4A depict the schematic cross section of another device 400, which also embodies some aspects of this invention. Device 400 may be a MOSFET or a rectifier.

The device 400 is similar to the device 300 depicted in FIG. 3. The two devices differ in the gate structure. While the gate electrodes in device 300 are disposed in gate trenches 390, the gate structure in device 400 is on the chip surface 441. The gate oxide 418 is disposed on the chip surface 441 under the gate electrodes 414, and which separates the gate electrode 414 from the epi-layers 440 and 430. Each gate structure is flanked on each side by field plate trenches 410 and 420. The structure of the field plate trenches of device 400 is similar to the structure of the field plate trenches of device 300.

### Example 5

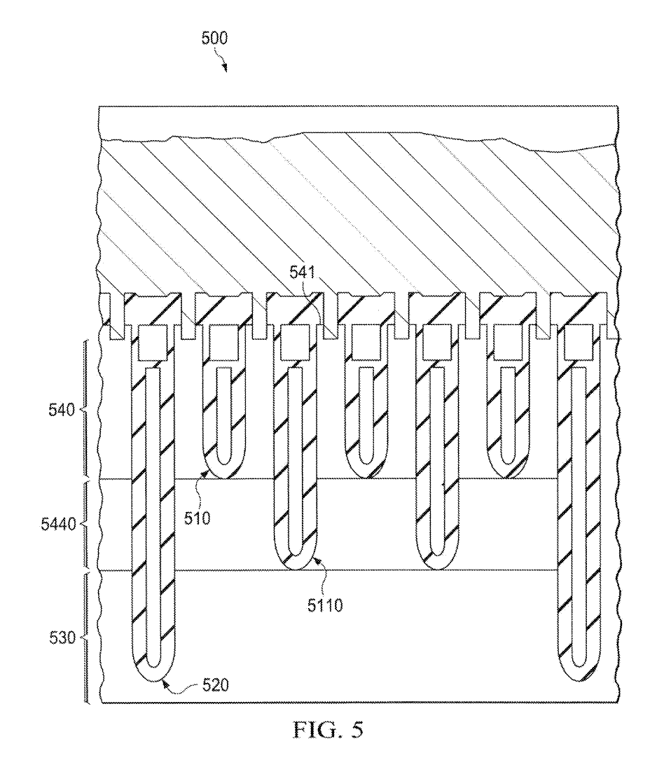

FIG. 5 depicts the schematic cross section of another device 500, which also embodies some aspects of this invention. Device 500 may be a MOSFET or a rectifier.

The device 500 is built in a semiconductor chip that comprises three epi-layers of different dopant concentration. The epi-layer 5440 is the more heavily doped than the epi-layer 530 but less heavily doped than the epi-layer 540, which is closest to the chip surface 541 than the epi-layers 5440 and 530.

Device 500 comprises a repetitive pattern of field plate trenches 510, 520, and 5110, all are etched into the semiconductor chip from the chip surface 541. The etching of the field plate trenches 510 stops when the bottoms reach the interface region of the epi-layers 540 and 5440. The field plate trenches 5110 are etched deeper than the trenches 510 and their bottoms reach the interface region of the epi-layer 5440 and 530. The field plate trenches 520 are etched deeper than the trench 5110. In this embodiment of the field plate trench continues through the interface region of the epi-layer 530 and the epi-layer 5440 above the epi-layer 530, and stops after the bottoms penetrate into the epi-layer 530.

In the repetitive pattern of field plate trenches of this exemplary device 500, each of the field plate trenches 5110 is flanked by the two shallower field plate trenches 510 on both sides; and two deeper field plate trenches 520 are disposed on the other side of each field plate trench 510 farther from the field plate trench 5110.

### Example 6

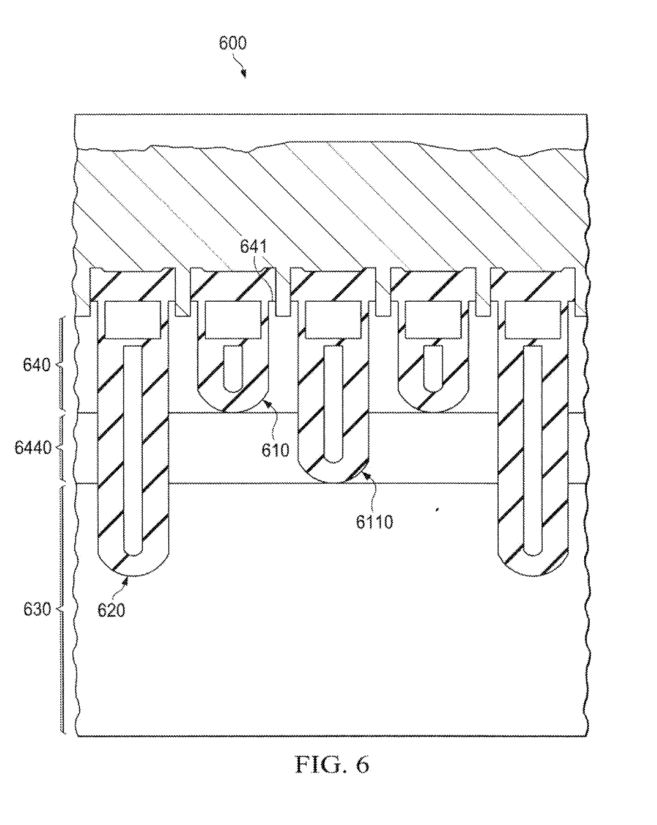

FIG. 6 depicts the schematic cross section of another device 600, which also embodies some aspects of this invention. Device 600 may be a MOSFET or a rectifier.

Similar to device 500, device 600 is built in a semiconductor chip that comprises three epi-layers of different dopant concentration. The epi-layer 6440 is the more heavily doped than the epi-layer 630 but less heavily doped than the epi-layer 640, which is closer to the chip surface 641 than the epi-layers 6440 and 630.

Device 600 comprises a repetitive pattern of field plate trenches 610, 620, and 6110, all are etched into the semiconductor chip from the chip surface 641. The etching of the field plate trenches 610 stops when the bottoms reach the interface region of the epi-layers 640 and 6440. The field plate trenches 6110 are etched deeper than the trench 610 and the bottoms reach the interface region of the epi-layers 6440 and 630. The field plate trenches 620 are etched deeper than the trench 6110. In this embodiment of the field plate trench continues through the interface region of the epi-layer 630 and the epi-layer above the epi-layer 630, and stops after the bottoms penetrate into the epi-layer 630.

In the repetitive pattern of field plate trenches of this exemplary device 600, every other field plate trench is a s440hallow field plate trench with its bottom at the transition region of two epi-layers of the same dopant polarity and with different dopant concentration.

### Example 7

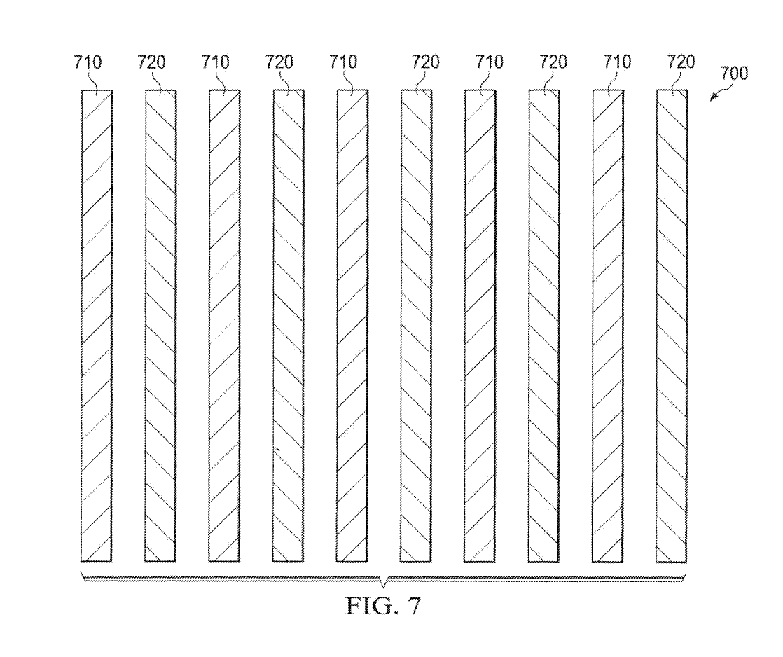

FIG. 7 depicts a schematic representation of a portion of a trench mask 700 that includes a repetitive pattern of two field plate trenches 710 and 720. This mask may be used in making MOSFET or rectifier as depicted in FIG. 1 through FIG. 6. The strips 710, for example, may correspond to the trenches 110 and the strips 720 may correspond to the trenches 120. Depending on specific designs, strips 710 and 720 may or may not have equal width.

1. A device, comprising:
a semiconductor chip with a repetitive pattern of field plate trenches of more than one depth disposed in the chip.

2. The device of claim 1, in which the semiconductor chip further comprises a top surface and a doped epi-layer, of which the dopant concentration is highest at near the top surface and progressively less heavy away from the top surface;

3. The device of claim 2, in which the epi-layer includes strata of epi-layers each having a different dopant concentration.

4. The device of claim 3, in which the field plate trenches with the deepest depth partially terminate in the least heavily doped epi-layer of the strata.

5. The device of claim 4, in which the trenches of a lesser depth terminate at the interface of two adjacent epi-layers.

6. The device of claim 1, in which each field plate trench is adjacent to a field plate trench of a different depth.

7. The device of claim 1, in which each field plate trench of the shallowest depth is adjacent to a field plate trench of the same depth.

8. The device of claim 1, in which every other field plate trench is a field plate trench of the shallowest depth. (FIG. 4)

9. The device of claim 1, in which the distance between two adjacent field plate trenches of the deepest depth is longer than or equal to the distance between two adjacent field plate trenches of equal but lesser depth.

10. The device of claim 2, in which the strata of epi-layers have the same doping polarity.

11. The device of claim 1, further comprising a repetitive pattern of gate structures of a MOSFET device or a rectifier device.

12. The device of claim 11, in which each gate structure comprises a gate electrode disposed within a trench.

13. The device of claim 12, in which the gate electrode is disposed within a field plate trench.

14. The device of claim 13, further comprising a filed plate electrode within each field plate trench.

15. The device of claim 14, in which the gate electrode and the field plate electrode in each field plate trench comprise doped polysilicon, and the gate electrode and the field plate electrode separated by a dielectric film.

16. A method of making a device, comprising:
providing a semiconductor chip having a top surface and a doped epi-layer parallel to the top surface with a dopant concentration that is heaviest at near the top surface and progressively less heavy away from the top surface; and
forming in the chip a repetitive pattern of field plate trenches of more than one depth, and perpendicular to epi-layer.

17. The method of claim 16, in which the epi-layer comprises strata of epi-layers of different dopant concentrations.

18. The method of claim 17, in which the forming step comprises bottoming the deepest trenches in the least heavily doped epi-layer.

19. The method of claim 17, in which the forming step comprises bottoming the lesser deep trenches at the interface (within +/−30% of transition region) of two adjacent epi-layers.

20. The method of claim 19, further comprising forming repetitive pattern of gate structures of a MOSFET device or a rectifier device.

21. The method of claim 20, in which a portion of each gate structure is formed within a field plate trench.
